(19) United States
(12) Patent Application Publication
(10) Pub. No.: US 2025/0047174 A1
(43) Pub. Date: Feb. 6, 2025

(54) ELECTRIC DRIVE DEVICE

(71) Applicant: HITACHI ASTEMO, LTD., Hitachinaka-shi, Ibaraki (JP)

(72) Inventors: Takuro KANAZAWA, Hitachinaka-shi, Ibaraki (JP); Kenichirou NAKAJIMA, Hitachinaka-shi, Ibaraki (JP); Tadashi SUGIURA, Hitachinaka-shi, Ibaraki (JP)

(73) Assignee: HITACHI ASTEMO, LTD., Hitachinaka-shi, Ibaraki (JP)

(21) Appl. No.: 18/717,755

(22) PCT Filed: Dec. 28, 2021
(86) PCT No.: PCT/JP2021/048978

§ 371 Date: Jun. 7, 2024

(51) Int. Cl. H02K 11/33; H02K 5/22

(52) U.S. Cl. CPC H02K 11/33; H02K 5/225

(57) ABSTRACT

An electric drive device includes a motor, an inverter, cooling water paths, a housing, a connector that connects the inverter and an external device, a fuse member connected to a bus bar extending from the inverter, and a connecting member including the same; in which the housing includes an accommodating portion that accommodates at least a part of the motor and the inverter, the connecting member is provided on a side wall of the housing, the fuse member is accommodated in the accommodating portion, and the inverter, the fuse member, and the connector are electrically connected.

### TECHNICAL FIELD

The present invention relates to an electric drive device.

### BACKGROUND ART

In the field of electric vehicles (xEV), it is required to output a power source of an air conditioner (A/C) via a high voltage direct current (HVDC) input to an inverter. On a circuit between the A/C and the inverter, a fuse that protects the electric circuit included in the A/C from overcurrent needs to be disposed, but in order to ensure stability of the fuse, the arranging location of the fuse in the electric drive device needs to be considered.

As a background art of the present invention, PTL 1 below discloses a configuration in which a fuse 84 is fixed and disposed near a cover 64 in a power conversion device 1.

### CITATION LIST

### Patent Literature

PTL 1: JP 2017-60267 A

### SUMMARY OF INVENTION

### Technical Problem

In the conventional art, since the fuse is disposed in the power conversion device, the fuse is likely to be affected by heat even though the fuse is disposed near the cover side, which may cause a problem in reliability of the fuse. In view of this, an object of the present invention is to provide an electric drive device that improves controllability while stabilizing a temperature environment around a fuse, and achieves miniaturization and standardization.

### Solution to Problem

An electric drive device includes a motor, an inverter, a housing that accommodates cooling water paths provided in the motor and the inverter, and a connecting member including a connector that connects the inverter and an external device and a fuse member connected to a bus bar extending from the inverter; in which the housing includes an accommodating portion that accommodates at least a part of the motor and the inverter, the connecting member is provided on a side wall of the housing, the fuse member is accommodated in the accommodating portion, and the inverter, the fuse member, and the connector are electrically connected.

### Advantageous Effects of Invention

According to the present invention, an electric drive device can be provided that improves controllability while stabilizing a temperature environment around a fuse, and achieves miniaturization and standardization.

### BRIEF DESCRIPTION OF DRAWINGS

FIG. 1 is an overall external view of an electric drive device according to one embodiment of the present invention.

FIG. 2 is a cross-sectional view of FIG. 1.

FIG. 3 is a simplified diagram illustrating positions of a fuse and an external connection connector in the electric drive device according to one embodiment of the present invention.

FIG. 4 is an explanatory diagram of components included in an inverter.

FIG. 5 is a diagram for describing a relationship between an inverter and a connecting member according to one embodiment of the present invention.

FIG. 6 is a power circuit diagram of an inverter connected to an A/C connector.

FIG. 7 is a diagram illustrating a modified example of a position of a fuse.

FIG. 8 is an explanatory view of the connecting member of FIG. 5.

Hereinafter, an embodiment of the present invention will be described with reference to the drawings. The following description and drawings are examples for describing the present invention, and are omitted and simplified as appropriate for the sake of clarity of description. The present invention can be carried out in various other forms. Unless otherwise specified, each component may be singular or plural.

Positions, sizes, shapes, ranges, and the like of the components illustrated in the drawings may not represent actual positions, sizes, shapes, ranges, and the like in order to facilitate understanding of the invention. Therefore, the present invention is not necessarily limited to the positions, sizes, shapes, ranges, and the like disclosed in the drawings.

(One embodiment and overall configuration of the present invention)

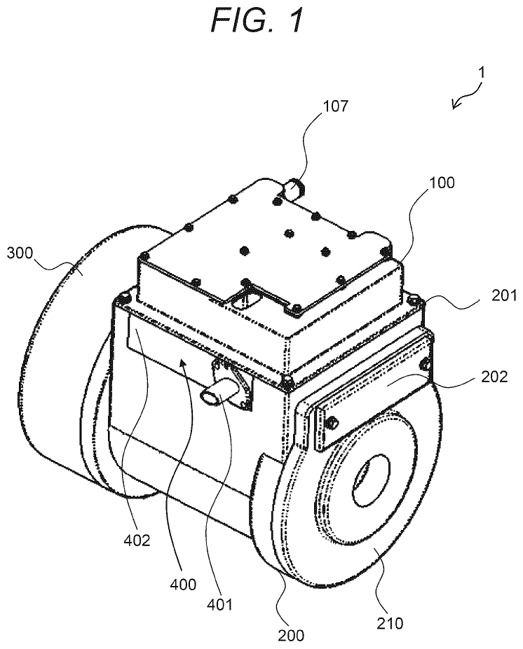

(FIG. 1)

The electric drive device 1 is an electric/mechanical integrated device in which an inverter 100 and a transmission 300 are disposed in a motor 200. The inverter 100 and the side cover 210 are respectively fixed to a motor housing 201, which is a housing, with bolts. The entire electric drive device 1 is fixed to the vehicle by way of a fixing portion (not illustrated) provided in the motor housing 201.

A pipe 107 for discharging cooling water flowing into the inverter 100 is provided outside the inverter 100. The flow for inflow and discharge may be reversed for the flow of the cooling water. The inverter 100 and the motor 200 are electrically connected through an AC terminal connecting portion cover portion 202. An external connection connector 401 for electrically connecting the inverter 100 and another device provided in the vehicle is provided on a side surface of the motor housing 201. The external connection connector 401 is provided as a part of the external connecting portion 400 which is a connecting member, and is fixed on the metal external connection cover 402.

The external connecting portion 400 is detachably connected to the inverter 100 and provided in the motor housing 201. An opening is provided in a side wall of the motor housing 201, and the external connecting portion 400 is attached so as to close the opening of the motor housing 201 and fixed to the motor housing 201 with a bolt or the like, so that the external connecting portion 400 and the motor housing 201 are integrated.

Note that the AC terminal connection cover portion 202 may also serve as (be common to) the external connecting portion 400, whereby the three-phase output terminal of the motor 200 is connected to the external connecting portion 400 of the motor housing 201, and the number of components is reduced.

Although FIG. 1 illustrates the inverter 100 in a configuration of being mounted on the motor housing 201, the inverter may be disposed on a side surface side of the motor housing 201 (motor 200). Furthermore, the external connection connector 401 may be provided anywhere as long as it is an outer peripheral portion of the motor 200.

The external connecting portion cover 402 has a seal (not illustrated) for watertightness provided in a portion in contact with the motor housing 201, but this seal may be installed on either side of the motor housing 201 or the external connecting portion cover 402.

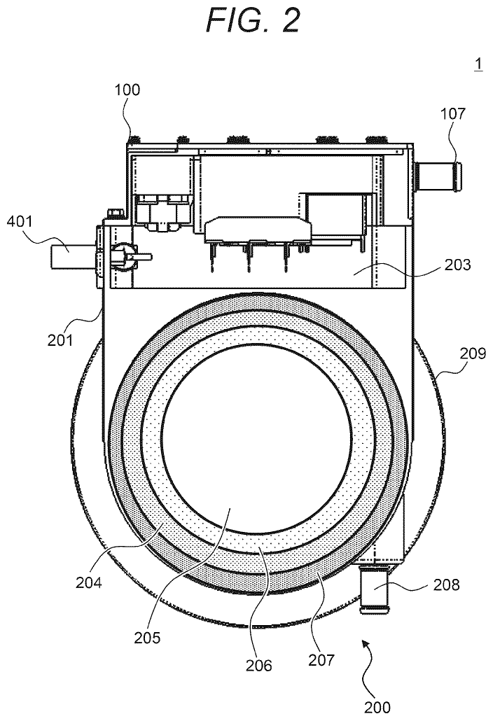

(FIG. 2)

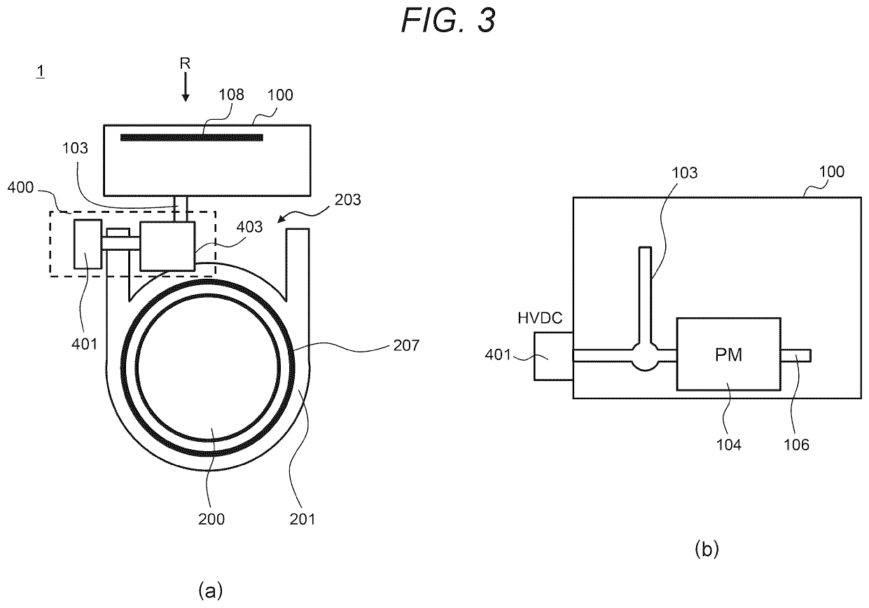

The motor 200 includes a rotor 205 and a stator 206 for converting electric energy into mechanical energy, and a stator housing 204 on the outer peripheral side thereof, and is stored in a motor accommodating portion 209. A cooling water path 207 is provided between the motor housing 201 and the stator housing 204 to cool the motor 200. The cooling water flowing in from the inverter water path 108 (FIG. 3 described later) is circulated in the cooling water path 207, and the cooling water is discharged to the outside of the motor 200 via the pipe 208.

The motor housing 201 is provided with a power converting portion accommodating portion 203 (hereinafter, the accommodating portion 203), and internal components of the inverter 100 coming out of the accommodating portion of the case of the inverter 100 can be arranged on the accommodating portion 203 side. An external connection connector 401 for connecting the inverter 100 and an external device is provided outside the accommodating portion 203 (outside the motor housing 201). The external connection connector 401 is an air conditioner connector (A/C connector) of a vehicle.

(FIG. 3)

The position of the fuse 403 in the electric drive device 1 will be described. Note that, FIG. 3(b) is a perspective view of the inverter 100 as viewed from the R direction of FIG. 3(a).

The motor accommodating portion 209 of the motor housing 201 accommodates the rotor 205, the stator 206, and the like for converting electric energy into mechanical energy, and is covered by the motor housing 201. Driving force generated by the motor 200 is transmitted to the vehicle by a shaft (not illustrated) included in the motor 200. The electric drive device 1 includes a connector (not illustrated) connected to a vehicle power supply.

The external connecting portion 400 includes a fuse 403 electrically connected to the external connection connector 401. The external connection connector 401 is connected to the A/C of the vehicle. The fuse 403 is arranged in the external connecting portion 400 in order to protect the electric circuit in this A/C from overcurrent. The external connection connector 401 and the fuse 403 are fixed to a housing side wall of the motor housing 201. The fuse 403 is disposed on the accommodating portion 203 side that is least thermally affected in the electric drive device 1.

In this way, the empty space of the motor housing 201 can be utilized, which contributes to the miniaturization of the electric drive device 1 and contributes to the exhibition of the stable performance of the electric drive device 1. Furthermore, the fuse 403 is less likely to be affected by heat than the case where the fuse is disposed in the inverter 100, and it is possible to further downsize the fuse 403 and to realize highly accurate control using the fuse 403.

The fuse 403 is electrically connected to the inverter 100 via a DC bus bar 103. As a result, the HVDC input to the inverter 100 is output to the external connection connector 401 via the fuse 403, and the direct current (DC) power is supplied from the external connection connector 401 to the A/C and the like of the vehicle. The fuse 403 and the external connection connector 401 are disposed at positions away from the cooling water path 207 of the motor 200. Since the accommodating portion 203 is located closer to the motor 200 than the inverter 100 and is thermally stable, the fuse 403 can be thermally stabilized by disposing the fuse 403 here, and improvement of reliability and high-performance control can be realized.

A cooling water path 207 is provided in the motor 200, and an inverter water path 108 is provided in the inverter 100, each of the water paths 108, 207 being connected by way of a connection water path (not illustrated) to cool the entire electric drive device 1.

The inverter 100 includes a power module 104, and an AC bus bar 106 connected to the power module 104 is connected to a motor output terminal of the motor 200. On the other hand, the power module 104 is electrically connected to the external connection connector 401 via the DC bus bar 103. As a result, the A/C power supply (power) can be output via the HVDC input to the inverter 100.

The external connecting portion 400 has a shape in which a fuse 403 is provided on a metallic external connecting portion cover 402 (details will be described later), and the external connection connector 401 is attached to the external connecting portion cover 402 (to the motor housing 201). In this way, since it is possible to receive the benefit of cooling of the cooling water path 207 on the motor 200 side, the heat dissipation is improved and thermal stabilization is realized.

In addition, the three-phase lines of the motor 200 and the inverter 100 are connected at the position of the accommodating portion 203 of the motor housing 201, but since the A/C connection is also at this position, the number of components can be reduced and workability can be improved. Note that the positions of the three-phase line connecting position between the motor 200 and the inverter 100 and the A/C connecting position can be made different, in which case, safety can be prioritized.

The inverter 100 and the A/C connector 401 are formed on the same plane in the electric drive device 1. In this way, the vehicle layout is improved.

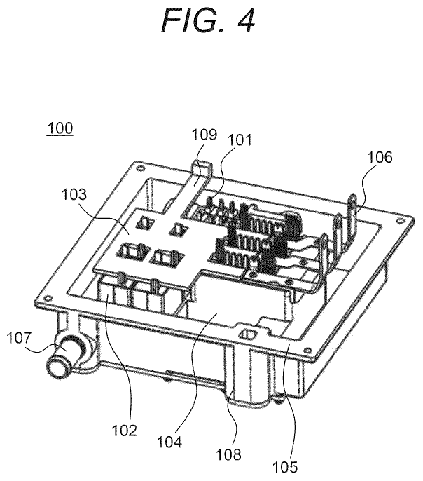

(FIG. 4)

FIG. 4 is a diagram of the inverter 100 as viewed from the motor 200 side. The case 105 of the inverter 100 has a shape opened to the motor 200 side. That is, since the inverter 100 does not have a cover for sealing internal components on the motor 200 side and is opened, it is fixed to the motor housing 201 in the open state.

The components of the inverter 100 protruding from the accommodating portion of the case 105 are not included in the layout of the inverter 100, and are accommodated in the accommodating portion 203 (FIGS. 1 and 3) of the motor housing 201. That is, the accommodating portion 203 has a function as an accommodating portion of the inverter 100. In this way, the bus bar layout of the inverter 100 can be simplified, and the cost is reduced.

The case 105 is provided with an inverter water path 108, and a pipe 107 for allowing cooling water flowing through the inverter water path 108 to flow in or out is provided outside. The position of the inverter water path 108 is illustrated on the near side in the plane of drawing in FIG. 4, but may be located anywhere on the side surface of the case 105.

The cooling water flowing in from the vehicle into the inverter 100 flows in from the pipe 107 and flows through a flow path (not illustrated) provided in the case 105 to cool the DC bus bar 103 and the power module 104 (FIG. 3). The cooling water flows into the flow path of the motor housing 201 via the inverter water path 108.

The DC power (not illustrated) from the vehicle is passed through an EMC filter 101 and a smoothing capacitor 102 provided in the inverter 100 and AC converted by the power module 104, so that the alternating current (AC) power is supplied to the motor 200. Here, the DC bus bar 103 for connecting the smoothing capacitor 102 and the power module 104 provided on the inverter 100 side is disposed closer to the motor 200 side (accommodating portion 203) than the inverter 100 side.

The DC bus bar 103 includes an A/C bus bar portion 109 that is connected to the external connecting portion 400 and supplies power to the A/C. The A/C bus bar portion 109 has a shape in which a terminal is bent toward the motor 200 side.

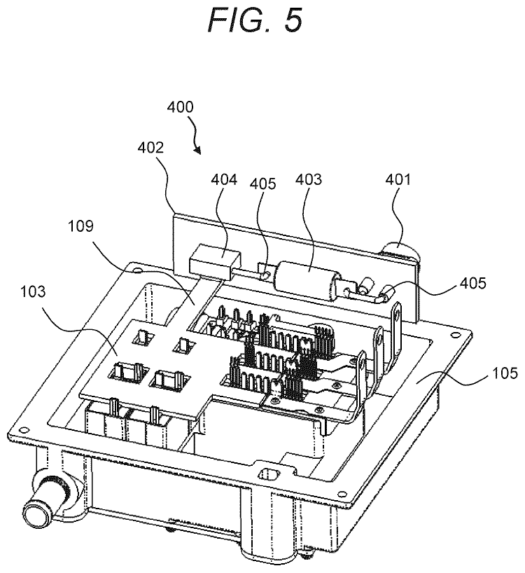

(FIG. 5)

As described above, the fuse 403 is disposed in the external connecting portion 400 connected to the A/C. The fuse 403 is required to receive electricity via the smoothing capacitor 102 having a stable voltage. For this reason, when the fuse 403 is disposed proximate to the side wall of the accommodating portion 203 as in the conventional structure, the distance from the external connection connector 401 provided in the inverter 100 may increase for the sake of design, and in this case, there is a problem that the size and cost of the electric drive device 1 may increase.

On the other hand, in the present invention, since the fuse 403 and the external connection connector 401 can be disposed proximate to each other by being mounted on and integrated with the external connecting portion cover 402, the wiring can be simplified, and the electric drive device 1 can be downsized.

The terminal block 404 is used to connect the connecting member 400 and the inverter 100 via the DC bus bar 103. The terminal block 404 has a shape of a female connector, and has a press-fit connecting structure by using the DC bus bar 103 as a male connector structure for connection. In this way, the male side of the connection can be shared (made common) by the DC bus bar 103 of the inverter 100, and the external connecting portion 400 can be easily attached to and detached from the DC bus bar of the inverter 100 and the motor housing 201, and workability in replacement of the fuse 403 is improved. Furthermore, it is possible to simultaneously achieve both the assembly of the electric drive device 1 and the connection between the inverter 100 and the A/C. In addition, if there is no problem in connection, the bolt for connecting the external connecting portion 400 with respect to the motor housing 201 can be eliminated.

In addition, since the DC bus bar 103 connected to the smoothing capacitor 102 is disposed on the motor 200 side (accommodating portion 203) as described above, the distance between the wiring on the inverter 100 side and the fuse 403 is minimized, and the wiring layout of both can be simplified. Furthermore, versatility corresponding to the type of connector and the current capacity is improved.

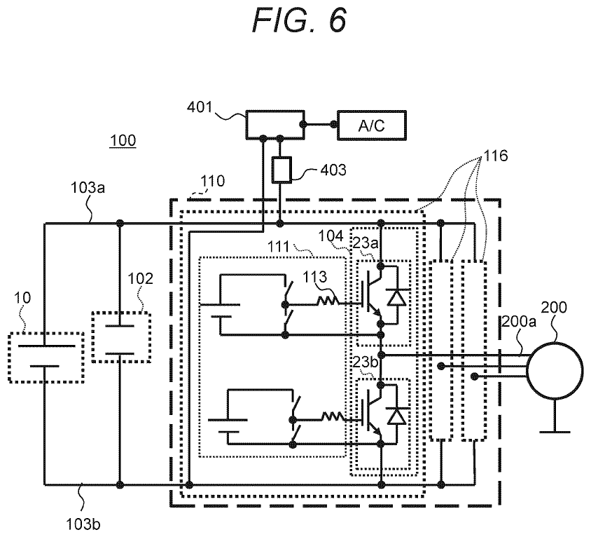

(FIG. 6)

A three-phase inverter circuit 110 included in the inverter 100 is connected in parallel with a battery 10 and the smoothing capacitor 102, and is supplied with DC power from the battery 10. The DC power is smoothed by the smoothing capacitor 102 connected in parallel. The smoothed DC power is converted into AC power by a semiconductor device 104 and output to the motor 200.

The three-phase inverter circuit 110 includes a three-phase 1-leg inverter 116 that integrates the semiconductor device 104 and the control circuit 111, and outputs a three-phase AC to the motor 200 by switching ON/OFF of switching. In FIG. 5, only one phase is shown, and illustration of the other two phases is omitted.

The current flowing through an upper arm element 23a and a lower arm element 23b of the semiconductor device 104 is switched between ON/OFF of the switching described above by a control signal output from the control circuit 111. The control signal output from the control circuit 111 is input to each of the upper arm element 23a and the lower arm element 23b through a signal wiring and a gate resistor 113.

The three-phase semiconductor device 104 is connected in parallel to each of a high-voltage side input wiring 103a and a low-voltage side input wiring 103b. Furthermore, the three-phase inverter circuit 110 is connected to a three-phase stator winding 200a of the motor 200 at an intermediate point connected in series with each of the upper arm semiconductor element 23a and the lower arm semiconductor element 23b.

The three-phase semiconductor device 104 is connected in parallel to the high-voltage side input wiring 103a and the low-voltage side input wiring 103b, and further includes a signal wiring and a signal wiring board (not illustrated) of the semiconductor device 104, and a control circuit 111, so that each of the upper arm semiconductor element 23a and the lower arm semiconductor element 23b is controlled by a signal input from the control circuit 111 via the signal wiring, and functions as a three-phase inverter circuit 110 that is an electric circuit device. Furthermore, the motor output terminal and the three-phase stator winding 200a of the motor 200 are connected, the smoothing capacitor 102 is connected to the high-voltage side input wiring 103a and the low-voltage side input wiring 103b, and the battery 10 is connected to the DC voltage input terminal, whereby the inverter 100 that converts the DC power into the AC power functions.

A positive electrode wiring and a negative electrode wiring connected to the inverter 100 are connected to the external connection connector 401, and are connected to the A/C by a harness or the like to supply DC power, and the fuse 403 is provided on the wiring on the positive electrode side of the wirings. The fuse 403 may be provided on the wiring on the negative electrode side, or the fuse 403 may be provided on both wirings.

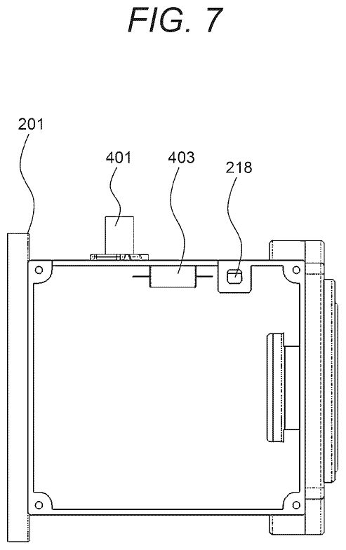

(FIG. 7)

Since the external connecting portion 400 is provided on the side wall of the motor housing 201, the external connection connector 401 protrudes outward from the side wall, and the fuse 403 is disposed on the inner side of the side wall. The fuse 403 is installed in contact with the side wall of the motor housing 201 on the same plane as the motor side water path 218, so that heat dissipation of the fuse 403 can be improved and reliability can be improved. Furthermore, further thermal stabilization can be achieved by disposing the fuse 403 proximate to the motor side water path 218.

Since the motor side water path 218 and the inverter water path 108 (FIG. 3) are connected to each other and formed on the same plane on the side surface of the inverter 100, the fuse 403 is also closely proximate to the inverter water path 108 and is thermally stable.

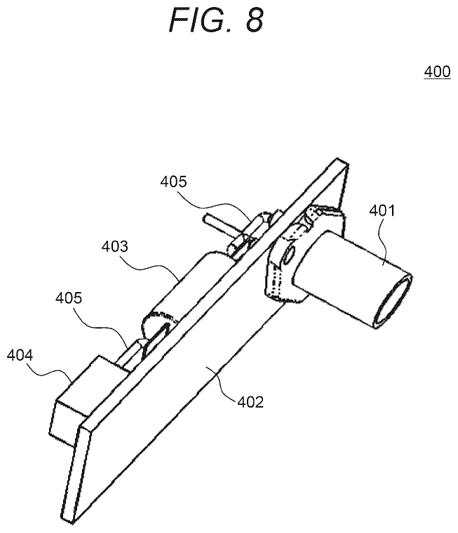

(FIG. 8)

The connecting member 400 has a bolt hole in the metal external connecting portion cover 402, and is screwed and fixed to the motor housing 201. Furthermore, the fuse 403 and the terminal block 404 included in the connecting member 400 are electrically connected by way of a wiring 405. The wiring 405 may be the DC bus bar 103.

As described above, by applying the detachable external connecting portion 400 including the fuse 403 to the motor housing 201, for example, even if the specification and installation position of the external connection connector 401 are changed when the vehicle to which the product is applied is changed in a vehicle manufacturer, the modification scale can be minimized and easily changed by changing only the external connection connector 401 and the external connecting portion cover 402. Similarly, even when the specification of the fuse 403 is changed (e.g., the capacity is changed), the design change scale can be minimized and easily changed. In addition, since components such as the fuse 403 are fixed to the external connecting portion cover 402, workability in replacing the fuse 403 can be improved. At the same time, it is possible to improve safety of electrical connection at the time of attaching and detaching the external connecting portion 400 and versatility accompanying cost reduction of the inverter 100.

As a modified example, the components of the fuse 403, the terminal block 404, and the wiring 405 may be disposed on the inner wall surface of the motor housing 201. In this case, for example, the opening of the motor housing 201 may have only an area for connecting the external connecting portion 401, and the seal portion may be provided in the external connecting portion 401. At this time, the fuse 403 may be easily replaced by opening a replacement window on the surface of the motor housing 201 facing the fuse 403. Furthermore, in order to secure the degree of freedom on the motor 200 side, the connection between the inverter 100 and the motor 200 and the position of the external connection connector 401 may be made different.

According to one embodiment of the present invention described above, the following operation effects are obtained.

(1) The electric drive device 1 includes a motor 200, an inverter 100, a housing 201 that accommodates cooling water paths 108, 207 provided in the motor 200 and the inverter 100, and a connecting member 400 including a connector 401 that connects the inverter 100 and an external device and a fuse member 403 connected to a bus bar 103 extending from the inverter 100. The housing 201 includes an accommodating portion 203 that accommodates at least a part of the motor 200 and the inverter 100, the connecting member 400 is provided on a side wall of the housing 201, the fuse member 403 is accommodated in the accommodating portion 203, and the inverter 100, the fuse member 403, and the connector 401 are electrically connected. In this way, the electric drive device 1 can be provided in which controllability is improved while stabilizing the temperature environment around the fuse 403 and miniaturization and standardization are achieved.

(2) The connecting member 400 is detachably connected to the inverter 100. With this configuration, the safety of the electrical connection at the time of attaching and detaching the external connecting portion 400 and the versatility accompanying the cost reduction of the inverter 100 can be enhanced.

(3) The bus bar 103 is electrically connected to the smoothing capacitor 102 included in the inverter 100, and is disposed closer to the accommodating portion 203 than to the inverter 100. This can contribute to downsizing of the electric drive device 1.

(4) The fuse member 403 is disposed in contact with a side wall of the housing 201 on the same plane as the cooling water path 108 provided in the inverter 100. In this way, the heat dissipation of the fuse 403 is improved.

(5) The connecting member 400 is fixed to the housing 201 so as to close an opening provided in a side wall of the housing 201. With such a configuration, the connecting member 400 electrically connected to the inverter 100 in a detachable manner can be achieved.

(6) An output terminal of the motor 200 is connected to the connecting member 400. With this configuration, the three-phase output terminal of the motor 200 is connected to the external connecting portion 400 of the motor housing 201, and the number of components is reduced.

(7) The connecting member 400 includes a female connector 404 and is connected to the inverter 100 by way of the female connector 404. In this way, the external connecting portion 400 is easily attached to and detached from the DC bus bar of the inverter 100 and the motor housing 201, and workability in replacement of the fuse 403 is improved.

(8) The female connector 404 is provided in a cover portion of the connecting member 400. With this configuration, the male side of the connection can be shared (made common) by the DC bus bar 103 of the inverter 100.

Note that the present invention is not limited to the above embodiments, and various modifications and other configurations can be combined within a scope not deviating from the gist of the present invention. In addition, the present invention is not limited to one including all the configurations described in the above embodiment, and includes one in which a part of the configuration is deleted.

### REFERENCE SIGNS LIST

1 electric drive device
10 battery
100 inverter
101 EMC filter
102 smoothing capacitor
103 DC bus bar
104 power module
105 case
106 AC bus bar
107 pipe (inverter side)
108 inverter water path
109 A/C bus bar portion
200 motor
201 motor housing
202 AC terminal connection cover portion
203 power converting portion accommodating portion
204 stator housing
205 rotor
206 stator
207 cooling water path
208 pipe
209 motor accommodating portion
210 side cover
218 motor side water path
300 transmission
400 external connecting portion
401 external connection connector
402 external connecting portion cover
403 fuse
404 terminal block
405 wiring

1. An electric drive device comprising:
a motor; an inverter; a housing that accommodates cooling water paths provided in the motor and the inverter; and a connecting member including a connector that connects the inverter and an external device and a fuse member connected to a bus bar extending from the inverter,
wherein the housing includes an accommodating portion that accommodates at least a part of the motor and the inverter,
the connecting member is provided on a side wall of the housing,
the fuse member is accommodated in the accommodating portion, and
the inverter, the fuse member, and the connector are electrically connected.

2. The electric drive device according to claim 1, wherein
the connecting member is detachably connected to the inverter.

3. The electric drive device according to claim 1, wherein
the bus bar is electrically connected to the smoothing capacitor included in the inverter, and is disposed closer to the accommodating portion than to the inverter.

4. The electric drive device according to claim 1, wherein
the fuse member is disposed in contact with a side wall of the housing on the same plane as the cooling water path provided in the inverter.

5. The electric drive device according to claim 1, wherein
the connecting member is fixed to the housing so as to close an opening provided in a side wall of the housing.

6. The electric drive device according to claim 1, wherein
an output terminal of the motor is connected to the connecting member.

7. The electric drive device according to claim 1, wherein
the connecting member includes a female connector and is connected to the inverter by way of the female connector.

8. The electric drive device according to claim 7, wherein
the female connector is provided in a cover portion of the connecting member.
